(19) United States
(12) Patent Application Publication
(10) Pub. No.: US 2026/0047139 A1
(43) Pub. Date: Feb. 12, 2026

(54) SEMICONDUCTOR DEVICE AND METHODS OF FORMING SAME

(71) Applicant: Taiwan Semiconductor Manufacturing Co.,Ltd., Hsinchu (TW)

(72) Inventors: Wan-Yi Kao, Baoshan Township (TW); Chunyao Wang, Zhubei City (TW); Tze-Liang Lee, Hsinchu (TW)

(21) Appl. No.: 18/800,378

(22) Filed: Aug. 12, 2024

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 30/6736

(57) ABSTRACT

In an embodiment, a method includes forming a first nanostructure and a second nanostructure over a substrate, the first nanostructure being interposed between the substrate and the second nanostructure; etching a first sidewall of the first nanostructure to be recessed from a second sidewall of the second nanostructure; depositing a first dielectric layer along the first sidewall, the second sidewall, and the substrate; etching a recess in the first dielectric layer, the recess extending toward the first sidewall of the first nanostructure; depositing a second dielectric layer in the recess over the first dielectric layer; and removing the first dielectric layer and the second dielectric layer from the second sidewall and the substrate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A-5B, 6A-6B, 7A-7C, 8A-8B, 9A-9D, 10A-10D, 11A-11D, 12A-12D, 13A-13H, 14A-14F, 15A-15B, 16A-16B, 17A-17D, 18A-18D, 19A-19C, 20A-20C, and 21A-21C illustrate varying views of intermediary steps of manufacturing a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nano-FETs. Various embodiments may be applied, however, to dies comprising other types of transistors (e.g., stacking transistors, or the like) in lieu of or in combination with the nano-FETs.

In various embodiments, a nano-FET is fabricated by forming a stack of layers (e.g., semiconductor layers) over a semiconductor substrate and patterning the stack into nanostructures. Some of the nanostructures comprise semiconductor layers which will become channel regions for the nano-FET (e.g., nanostructure channels), and others of the nanostructures comprise a sacrificial material (e.g., additional semiconductor layers or oxide layers) which will be removed and replaced with a gate structure. Before removing the sacrificial material, the sacrificial material is recessed from sidewalls of the nanostructure channels). Inner spacers are formed in those recesses by depositing a first inner spacer layer, etching portions of the first inner spacer layer, depositing a second inner spacer layer, and etching portions of both the first and second inner spacer layers. Selection of the compositions, deposition processes, and shaping of the first and second inner spacer layers allows for the inner spacers to be formed seam-free or with reduced seams, which improves the integrity and functionality of the inner spacers. Source/drain regions are then epitaxially grown over the sidewalls of the nanostructure channels such that the source/drain regions eventually extend over the inner spacers. The sacrificial material is then replaced with a gate structure (e.g., one or more gate dielectric layers and a gate electrode) to form the nano-FET. As a result of the embodiments described herein, the nano-FET may be fabricated at a greater yield and function with improved reliability and performance.

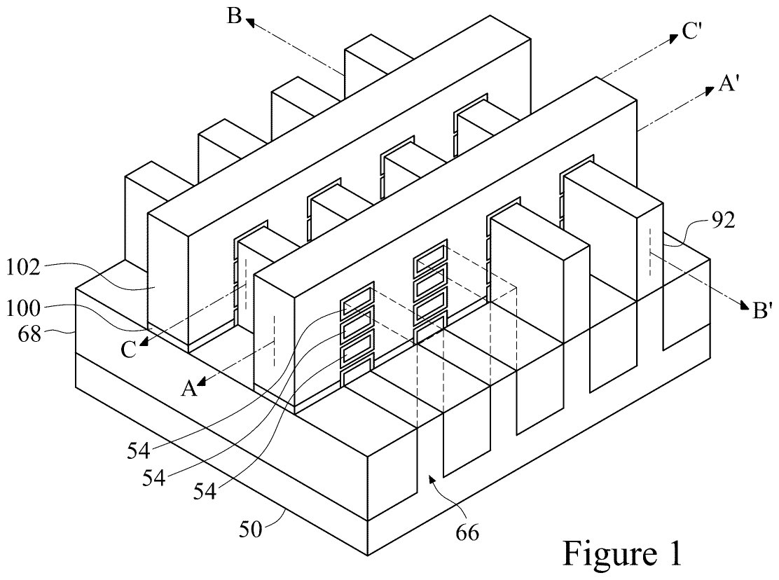

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise second nanostructures 54 (e.g., nanosheets, nanowire, or the like) over fins 66 on a substrate 50 (e.g., a semiconductor substrate), wherein the second nanostructures 54 act as channel regions for the nano-FETs. The second nanostructures 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the second nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

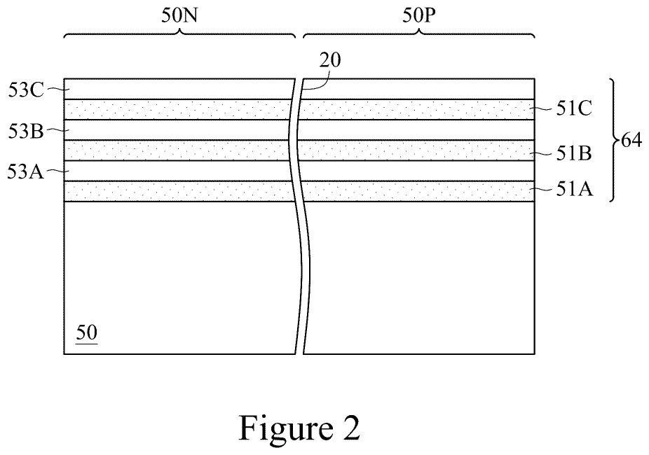

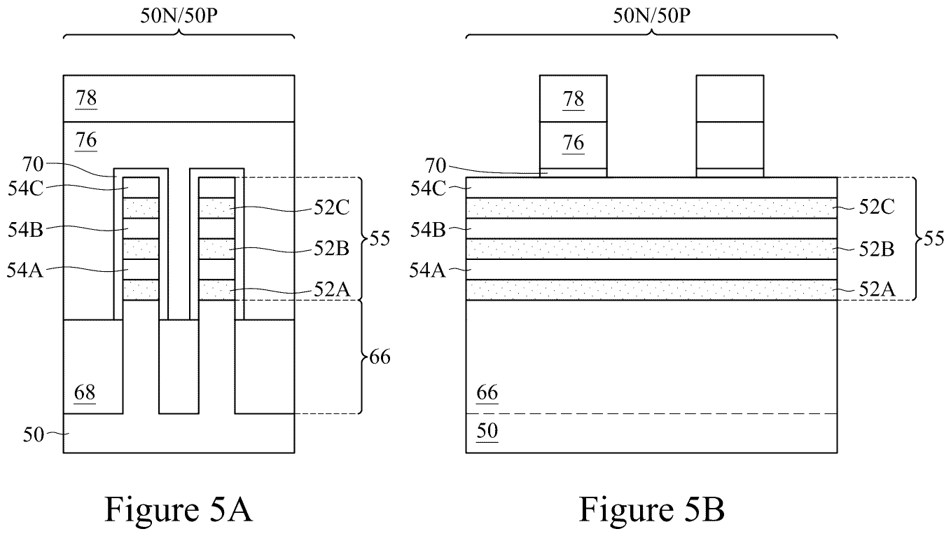

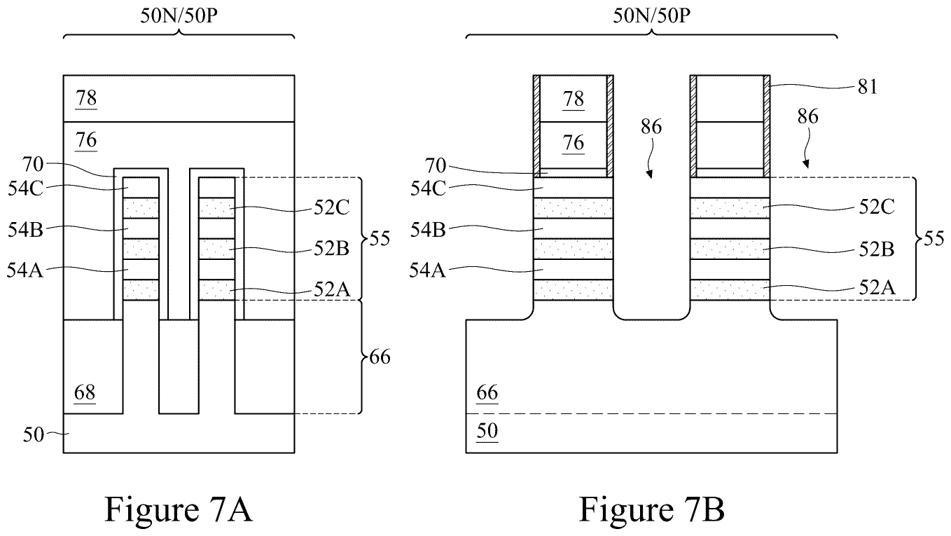

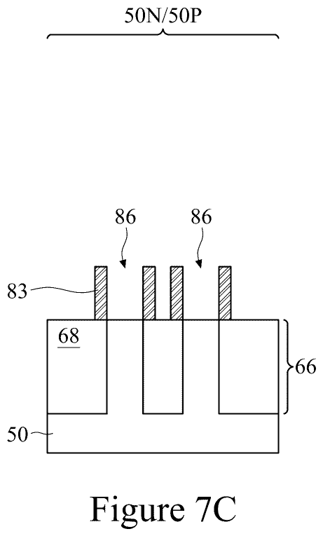

FIGS. 2 through 21C are cross-sectional views of intermediate stages in the manufacturing of nano-FETs, in accordance with some embodiments. FIGS. 2-4, 5A, 6A, 7A, 8A, 9A, 10A, 11A, 12A, 13A, 14A, 15A, 16A, 17A, 18A, 19A, 20A, and 21A illustrate reference cross-section A-A′ illustrated in FIG. 1. FIGS. 5B, 6B, 7B, 8B, 9B-9D, 10B-10D, 11B-11D, 12B-12D, 13B-13H, 14B-14D, 15B, 16B, 17B-17D, 18B-18D, 19B, 20B, and 21B illustrate reference cross-section B-B′ illustrated in FIG. 1. FIGS. 7C, 14E, 14F, 19C, 20C, and 21C illustrate reference cross-section C-C′ illustrated in FIG. 1.

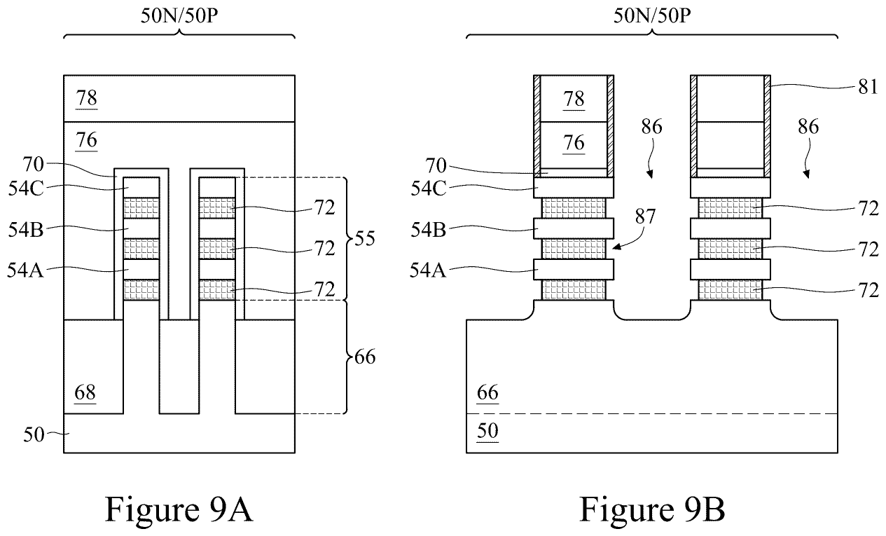

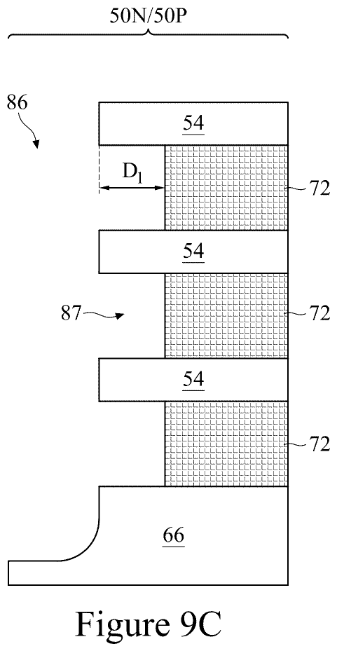

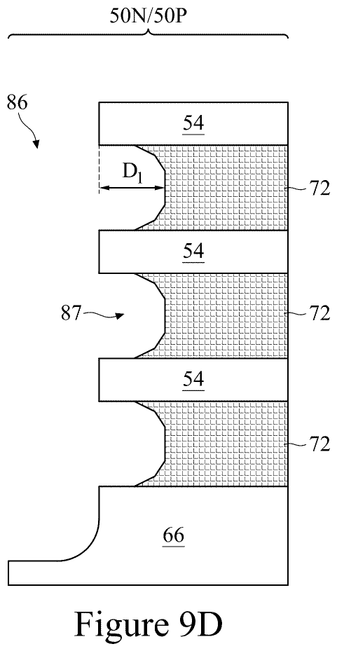

Moreover, FIGS. 9D, 10D, 11D, 12D, 13D, 14D, 17D, and 18D illustrate embodiments in which certain elements are depicted with modified shapes and/or dimensions due to practicalities (e.g., realities) in the corresponding process steps. For the sake of simplicity and clarity, these embodiments may be referred to as “practical embodiments.” For example, the figures illustrating the practical embodiments may indicate where certain elements may have roundedness or curvature after formation or alteration by subsequent processes (or other notable distinctions from the other figures depicting the corresponding process steps). Moreover, these figures continue from one another, and therefore each subsequent figure may be affected by the practicalities illustrated in the previous figure(s).

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions. As such, in some embodiments, the first semiconductor layers 51 may comprise crystalline silicon germanium while the second semiconductor layers 53 may comprise crystalline silicon, and vice versa.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

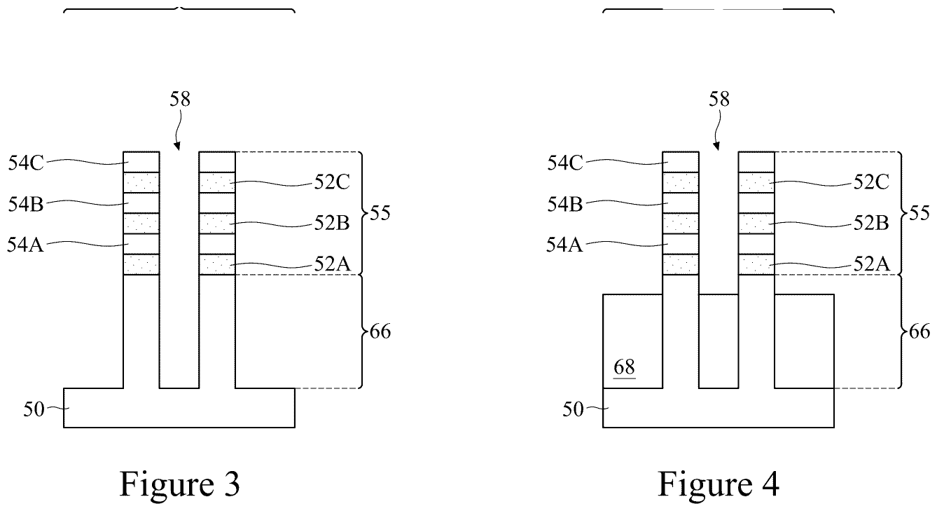

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

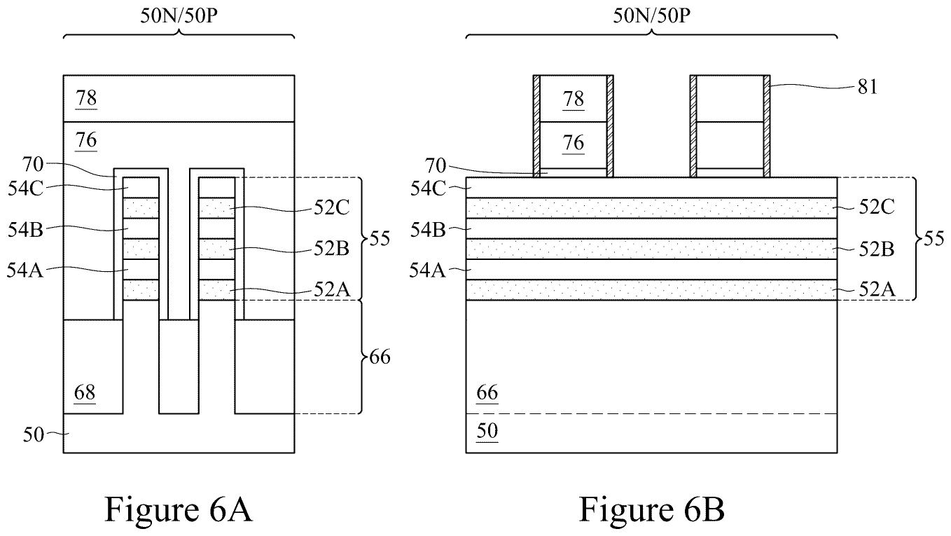

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

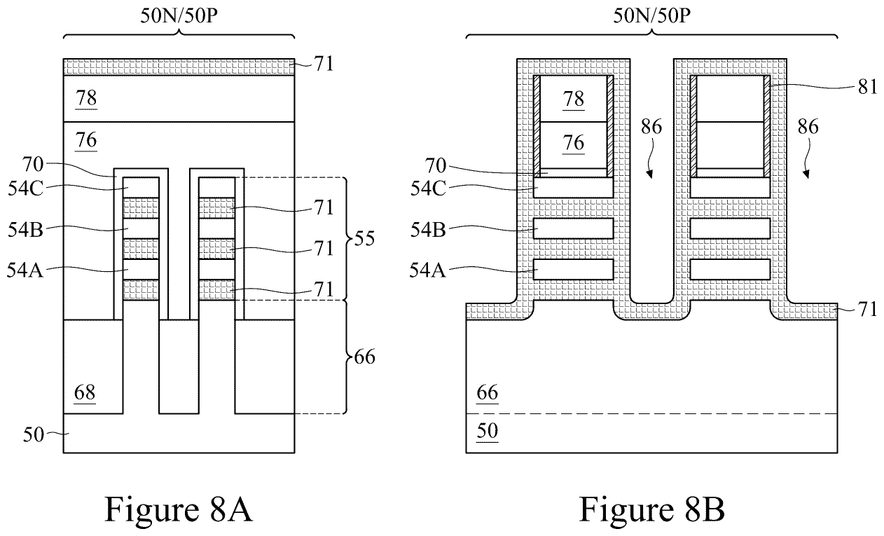

Optionally, FIGS. 8A-9B illustrate replacing the first nanostructures 52 with a sacrificial material 72 (also referred to as disposable oxide interposers (DOI)). As such, the sacrificial material 72 may also be considered nanostructures (e.g., dielectric nanostructures).

In FIGS. 8A and 8B, replacing the first nanostructures 52 may include etching away the first nanostructures 52 using a suitable etch process, such as an isotropic etch process, that is performed through the first recesses 86. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material layer 71 is deposited in the recesses 86 and spaces where the first nanostructures 52 were removed. The sacrificial material layer 71 may be deposited by a conformal deposition process, such as CVD, ALD, or the like. The sacrificial material layer 71 may comprise an insulating material such as silicon oxide (e.g., SiO₂), or the like that can be selectively etched from the second nanostructures 54.

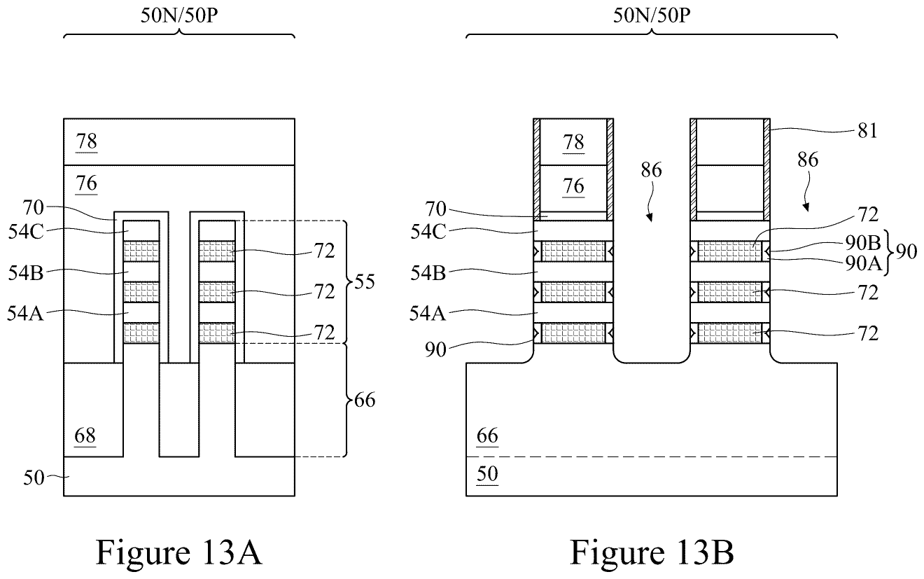

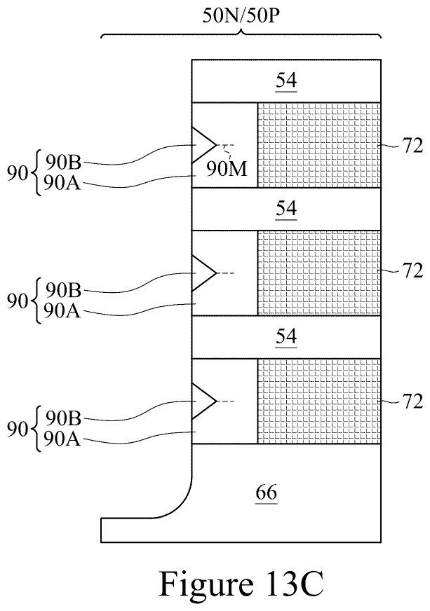

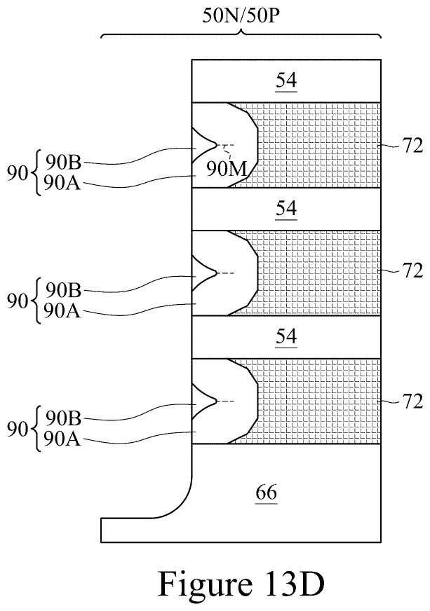

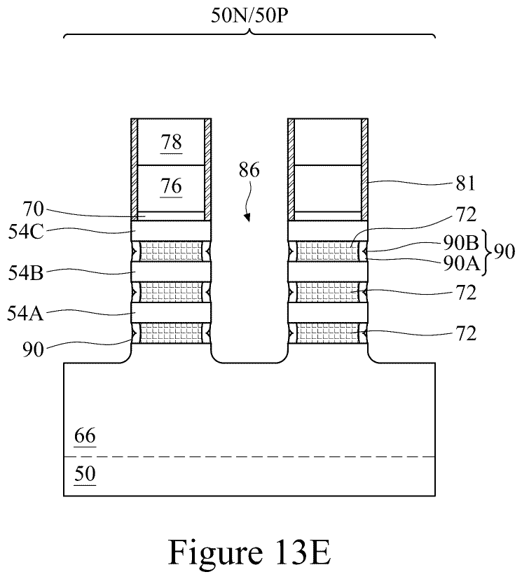

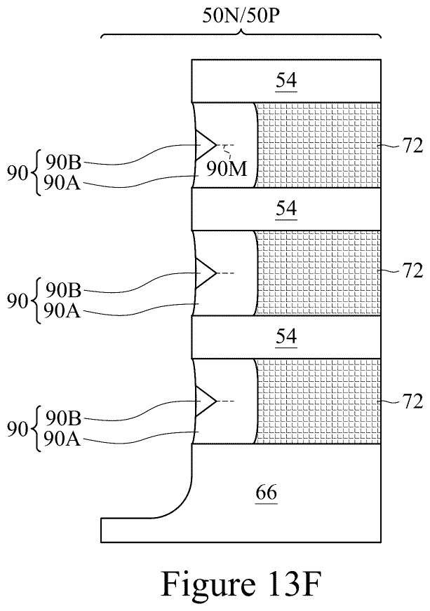

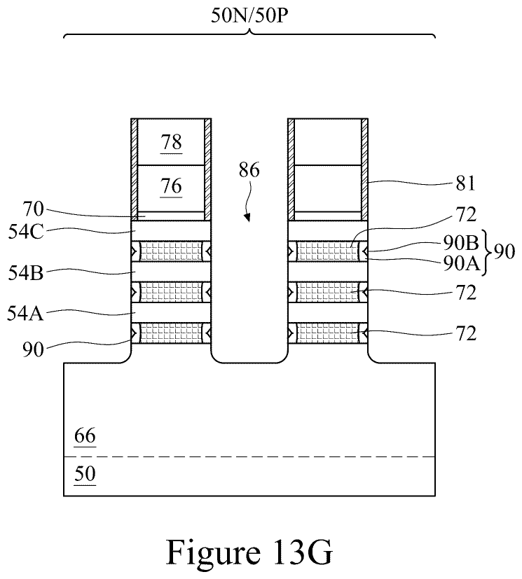

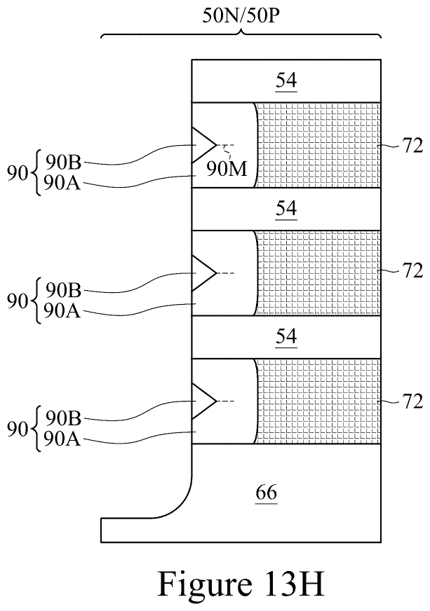

In FIGS. 9A-9D, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed to form recesses 87 in sidewalls of the sacrificial material 72 from sidewalls of the second nanostructures 54. Although the sidewalls of the sacrificial material 72 are illustrated as being straight in FIGS. 9B and 9C, the sidewalls may be concave or convex (see, e.g., FIGS. 9D, 13E-13H).

FIGS. 9C and 9D illustrate exemplary detailed views of various elements of FIG. 9B, including the second nanostructures 54, the fins 66, and the sacrificial material 72. As illustrated, the sacrificial material 72 may be recessed to a depth D₁ ranging from 5 nm to 10 nm (e.g., from 6 nm to 7 nm), although the sacrificial material 72 (or the first nanostructures 52) may be recessed to any suitable depth D₁.

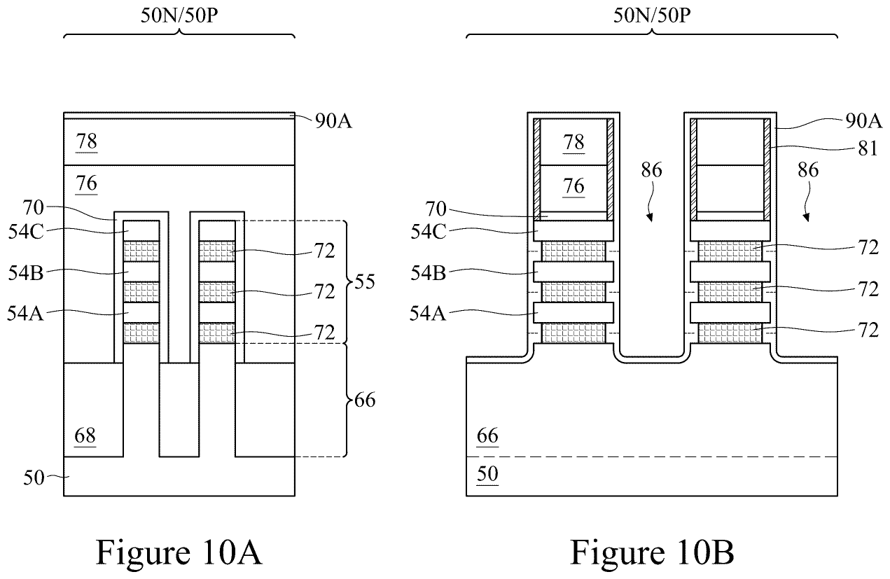

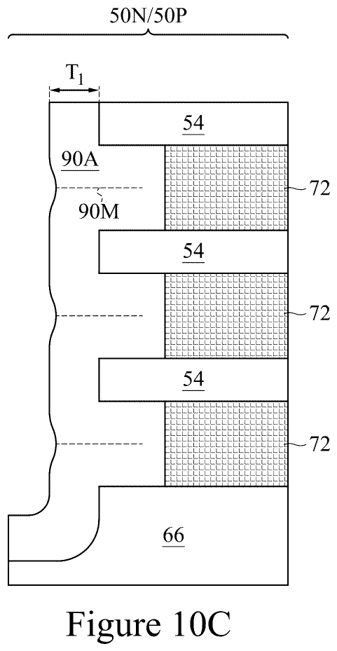

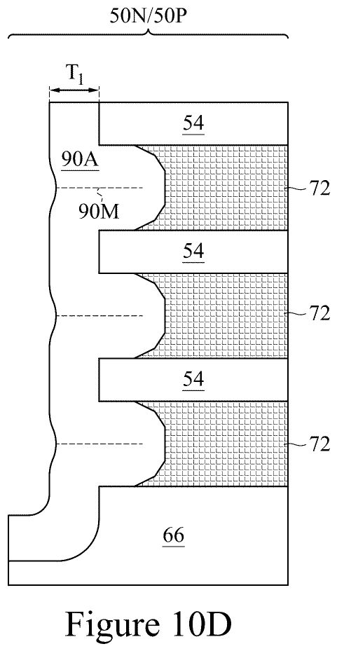

As discussed above, FIG. 9D illustrates an embodiment similar to FIG. 9C, but wherein some elements may be depicted with modified shapes and/or dimensions due to practicalities (e.g., realities) in the process step. In addition, FIGS. 10D, 11D, 12D, 13D, 14D, 17D, and 18D may be considered among the “practical embodiments”along with FIG. 9D.

Referring again to FIG. 9D, after performing the etch process, the sidewalls of the sacrificial material 72 may have a concave shape such that regions of the sacrificial material 72 along the second nanostructures 54 are recessed less than middle regions.

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

As noted above, the process steps of FIGS. 8A-9B are optional and may be performed for none or some of the nanoFETs. For example, in some embodiments (not specifically illustrated), the first nanostructures 52 remain at this point in the process, and the sacrificial material layer 71 is not deposited. Instead, an etch process is performed to recess sidewalls of the first nanostructures 52. This etch process may be performed similarly as described above in connection with FIGS. 8A-8B (e.g., removal of the first nanostructures 52), albeit halting the etch process at a desired degree of recessing rather than a complete removal of the first nanostructures 52. In some embodiments, the etch process is an anisotropic etch process such as RIE, NBE, or the like. Note that subsequent figures illustrate the intermediate structures as including the sacrificial material 72. It should be appreciated that the corresponding shapes and dimensions of the first nanostructures 52 may be substantially the same as those illustrated for the sacrificial material 72, unless otherwise stated. As such, labels in the figures for the sacrificial material 72 (or portions thereof) may alternatively apply to the first nanostructures 52 (or portions thereof).

FIGS. 10A-13H illustrate embodiments of a seam control process for forming inner spacers 90 in the recesses 86 on the sidewalls of the sacrificial material 72 (or of the first nanostructures 52, if still present). The inner spacers 90 act as isolation features between subsequently formed source/drain regions and a gate structure. As discussed in greater detail below, source/drain regions will be formed in the recesses 86, and the sacrificial material 72 (or first nanostructures 52) will be replaced with corresponding gate structures. The inner spacers 90 may also be used to prevent damage to the subsequently formed source/drain regions by subsequent etching processes, such as etching processes used to form the gate structures.

The seam control process is used to form the inner spacers 90 as either seam-free or with small seams in order to increase reliability and improve performance of the inner spacers 90. As discussed in greater detail below, the inner spacers 90 may be formed in a deposition-etch-deposition process by depositing a first inner spacer layer over the structures illustrated in FIGS. 9A-9D, performing an etch process, and depositing one or more second inner spacer layers over the etched first inner spacer layer. The inner spacer layers comprise materials selected to provide an effective dielectric constant (e.g., an effective k-value) that is sufficiently low while further providing benefits of etch resistance (e.g., etch selectivity in comparison with certain other features) during subsequent process steps.

In FIGS. 10A-10D, a first inner spacer layer 90A is deposited along exposed surfaces of the structure, such as in the recesses along exposed surfaces of the fins 66, sidewalls of the sacrificial material 72, sidewalls of the second nanostructures 54, sidewalls of the gate spacers 81, and upper surfaces of the masks 78 (if present). In accordance with various embodiments, the first inner spacer layer 90A may be a silicon-based low-k material, such as a silicon oxycarbide (SiCₓO_{y}) or a silicon oxycarbonitride (SiCₓO_{y}N_{z}) with a low nitrogen concentration.

For example, the first inner spacer layer 90A may be formed with a silicon concentration ranging from 25% to 35% by atomic weight (e.g., 30% at. wt.), a carbon concentration ranging from 5% to 20% by atomic weight (e.g., 6% at. wt.), an oxygen concentration ranging from 60% to 70% by atomic weight (e.g., 64% at. wt.), and a nitrogen concentration of less than or equal to 10% by atomic weight (e.g., 0% at. wt.).

In some embodiments, the first inner spacer layer 90A may be deposited by any suitable method, such as CVD, plasma-enhanced CVD (PECVD), or ALD using precursors including silane, dichlorosilane (DCS), hexachlorodisilane (HCD), hydrogen gas, oxygen gas, the like, or combinations thereof. In addition, the deposition process may be performed at temperatures up to between 300° C. and 700° C. (e.g., up to about 550° C.). Further, the first inner spacer layer 90A may have a dielectric constant (e.g., k-value) of less than about 4 (e.g., about 3.8). The first inner spacer layer 90A having a k-value of less than about 4 contributes to the inner spacer 90 having a sufficiently low effective dielectric constant in order to improve performance of the nanoFETs. In some embodiments, the first inner spacer layer 90A as deposited may have a density ranging from 2.00 g/cm³ to 2.50 g/cm³ (e.g., 2.23 g/cm³) and a stress greater than about 0 GPa and up to about −0.05 GPa (e.g., a compressive stress).

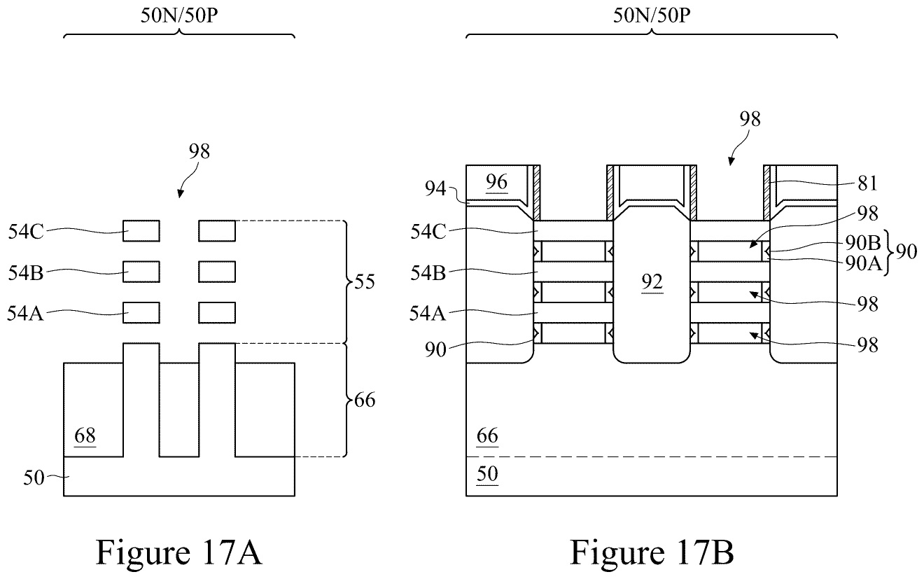

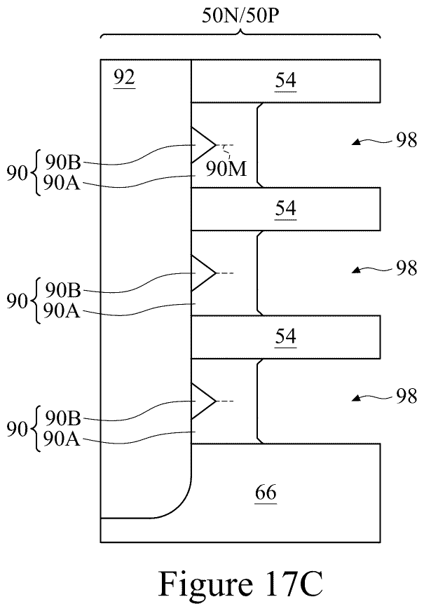

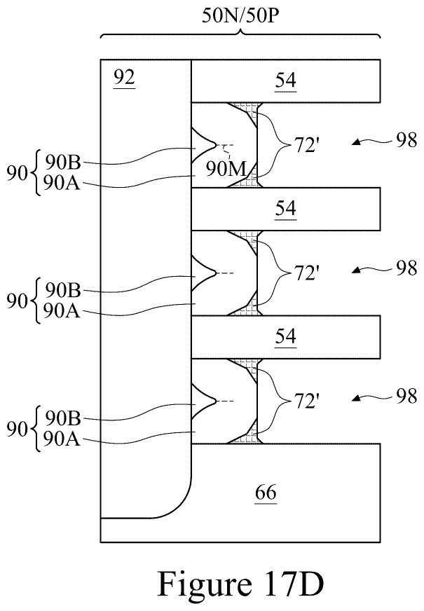

Forming the first inner spacer layer 90A as described above achieves various benefits. For example, the low dielectric constant ensures that the inner spacer 90 (see FIGS. 13A-H) have a low effective dielectric constant. Indeed, having a low nitrogen concentration and a high oxygen concentration (e.g., the oxygen concentration being greater than the nitrogen concentration) contributes to the low-k value for the first inner spacer layer 90A. In addition, the first inner spacer layer 90A has a high etch selectivity with the sacrificial material 72 (e.g., silicon oxide). Presence of carbon in the concentrations described above assists in this etch selectivity, which provides the first inner spacer layer 90A with etch resistance during subsequent removal of the sacrificial material 72 (see FIGS. 17A-17D).

FIGS. 10C and 10D illustrate exemplary detailed views of various elements of FIG. 10B, including the second nanostructures 54, the fins 66, the sacrificial material 72, and the first inner spacer layer 90A. As illustrated, the first inner spacer layer 90A may be conformally deposited along the recessed sidewalls of the sacrificial material 72. The first inner spacer layer 90A may be deposited with a thickness T₁ ranging from 20 Å to 30 Å, however any suitable thickness T₁ may be utilized such that portions of the first inner spacer layer 90A along upper and lower surfaces of the second nanostructures 54 will come together during deposition. As illustrated, these portions may converge where they form seams 90M. The seams 90M start at an outward sidewall of the first inner spacer layer 90A and extend toward (albeit, partially) toward the inward sidewall of the first inner spacer layer 90A (e.g., toward the sacrificial material 72).

In particular, FIG. 10D (e.g., of the practical embodiments) illustrates that the sidewalls of the sacrificial material 72 having concave shapes may cause inward sidewalls of the first inner spacer layer 90A to have convex shapes along the sidewalls of the sacrificial material 72. Moreover, the outward sidewall of the first inner spacer layer 90A may include dishing in regions laterally adjacent to the recessed sacrificial material 72.

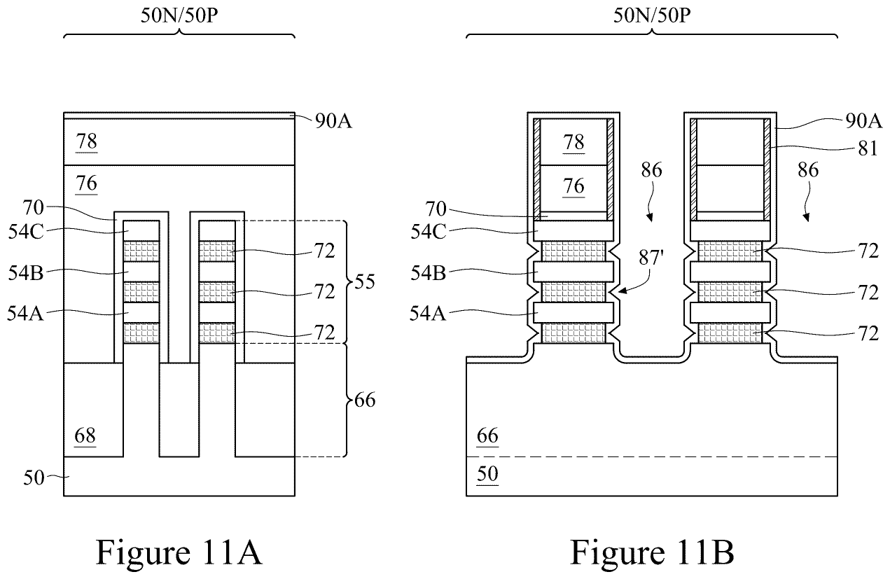

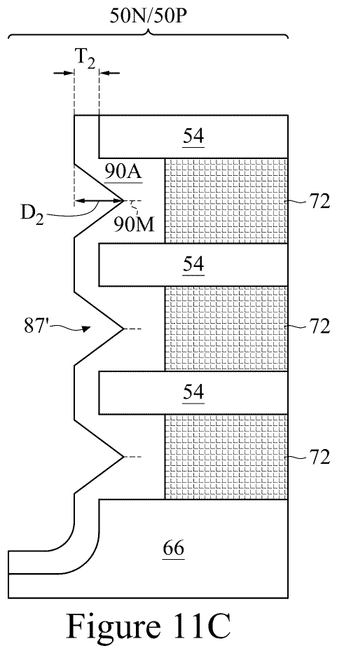

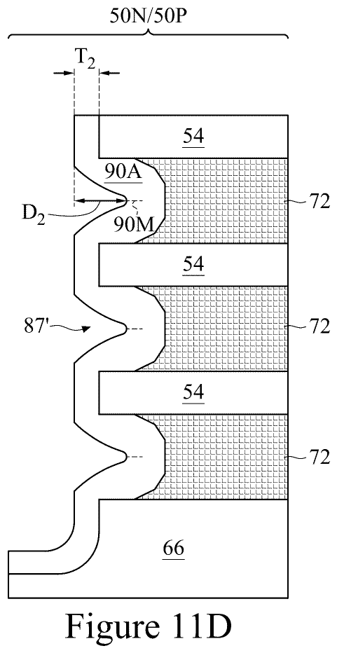

In FIGS. 11A-11D, the first inner spacer layer 90A is etched to form recesses 87′ at the seams 90M. In particular, an etch process forms the recesses 87′ to have a lower critical dimension than the recesses 87. In other words, windows for the recesses 87′ are proportionately larger (e.g., wider or smaller angles from vertical) in relation to the depth D₂ as compared to windows for the recesses 87 in relation to the depth D₁. In addition, the seams 90M are shortened. In some embodiments (not specifically illustrated), the etching may remove enough of the first inner spacer layer 90A to remove some or all of the seams 90M. The etch process may be an isotropic etch or an anisotropic etch using nitrogen trifluoride (NF₃) and/or any other suitable etchant(s).

FIGS. 11C and 11D illustrate exemplary detailed views of various elements of FIG. 11B, including the second nanostructures 54, the fins 66, the sacrificial material 72, and the first inner spacer layer 90A (e.g., including recesses 87′). In some embodiments, the recesses 87′ may have a depth D₂ ranging from 20 Å to 50 Å. In addition, the etch process may thin other portions of the first inner spacer layer 90A to a thickness T₂ ranging from 10 Å to 20 Å, or about 50% to 60% of the thickness T₁. It should be appreciated that portions of the first inner spacer layer 90A deeper within the recesses 87 (e.g., between the second nanostructures 54 and proximal to the sacrificial material 72) may be etched to a thickness of about 65% to 75% of the thickness T₁. For example, the depth D₂ of the recesses 87′ may be greater than the thickness T₂ such that the recesses 87′ extend to between and past the sidewalls of the second nanostructures 54. As illustrated, the recesses 87′ may have a substantially triangular shape wherein two sides of the triangle are portions of the outward sidewalls of the first inner spacer layer 90A.

In particular, FIG. 11D (e.g., of the practical embodiments) illustrates that the two sides of the triangular shape of the recesses 87′ may be concave and meet at a rounded point (e.g., located at or near the seam 90M). However, due to effects or inconsistencies in the etch process, it should be appreciated that either or both of the two sides may be concave, convex, or substantially straight while meeting at the rounded point.

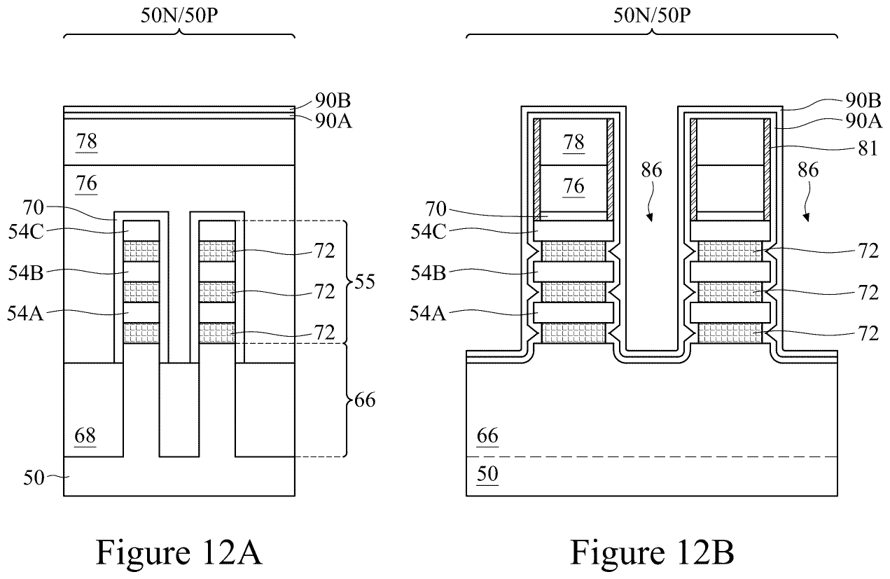

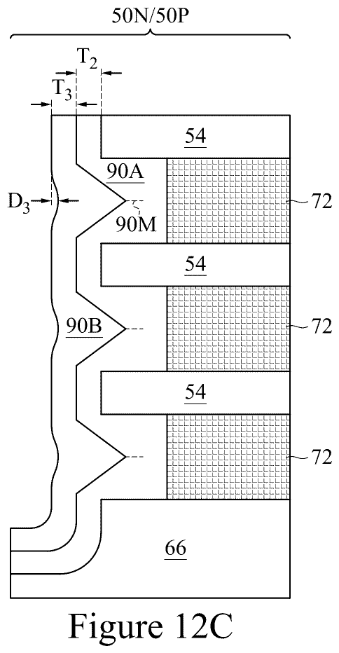

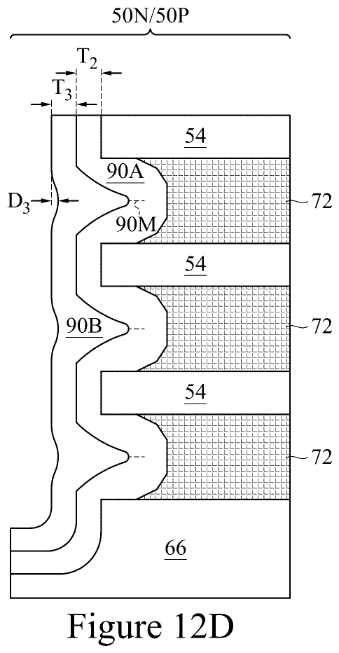

In FIGS. 12A-12D, a second inner spacer layer 90B is formed over the first inner spacer layer 90A and within the recesses RCS adjacent to the sacrificial material 72 (or the first nanostructures 52) and between neighboring second nanostructures 54. As illustrated, the second inner spacer layer 90B fills entireties of the recesses 87′ with the second inner spacer layer 90B being free of seams. This result is due, in part, to the windows of the recesses 87′ being greater than (or having a lower critical dimension than) the recesses 87 within which the first inner spacer layer 90A was deposited. In accordance with various embodiments, the second inner spacer layer 90B may be a silicon-based material, such as a silicon nitride (SiₐN_{d}) wherein a ratio of a:d is between 0.75 and 0.85 (e.g., 0.816). In some embodiments, the second inner spacer layer 90B may be a silicon oxycarbonitride (SiₐC_{b}O_{c}N_{d}).

For example, the second inner spacer layer 90B may be formed with a silicon concentration ranging from 30% to 35% by atomic weight (e.g., 32% at. wt.), a carbon concentration ranging from 2% to 20% by atomic weight (e.g., 5% at. wt.), an oxygen concentration ranging from 30% to 50% by atomic weight (e.g., 43% at. wt.), and a nitrogen concentration ranging from 15% to 35% by atomic weight (e.g., 20% at. wt.). Note that the second inner spacer layer 90B may include another metalloid, e.g., boron, instead of silicon, such as comprising boron oxycarbonitride (BₐC_{b}O_{c}N_{d}). In various embodiments, the first and second inner spacer layers 90A/90B may have similar silicon concentrations (or metalloid concentrations) and similar carbon concentrations, while the first inner spacer layer 90A has a greater oxygen concentration and the second inner spacer layer 90B has a greater nitrogen concentration.

In some embodiments, the second inner spacer layer 90B may be deposited by any suitable method, such as ALD (e.g., thermal ALD), using precursors including hexachlorodisilane, propene, oxygen gas, ammonia, the like, or combinations thereof. In embodiments in which the second inner spacer layer 90B is silicon nitride, then the precursors may include hexachlorodisilane, ammonia, and/or the like. In addition, the deposition process may be performed at temperatures up to between 500° C. and 700° C. (e.g., up to about 630° C.). Further, the second inner spacer layer 90B may have a k-value of less than about 7, such as ranging from 5.0 (e.g., SiCON) to 6.5 (e.g., SiN). The second inner spacer layer 90B having a k-value of less than about 7 (e.g., in combination with the first inner spacer layer 90A) ensures that the inner spacer 90 has a sufficiently low effective dielectric constant in order to improve performance of the nanoFETs. In some embodiments, the second inner spacer layer 90B as deposited may have a density ranging from 2.40 g/cm³ to 2.85 g/cm³ (e.g., ranging from 2.48 g/cm³ to 2.85 g/cm³) and a stress ranging from about 0.23 GPa to about 0.26 GPa (e.g., a tensile stress).

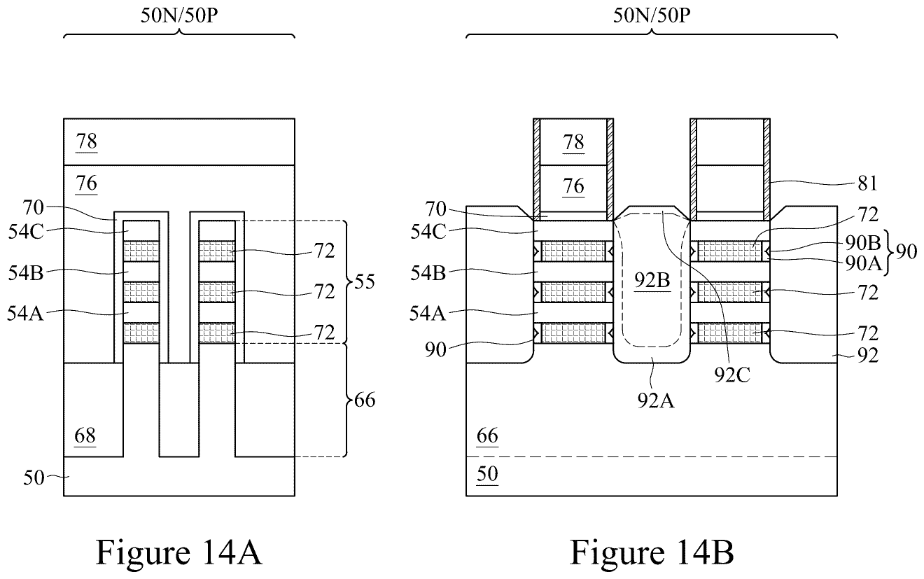

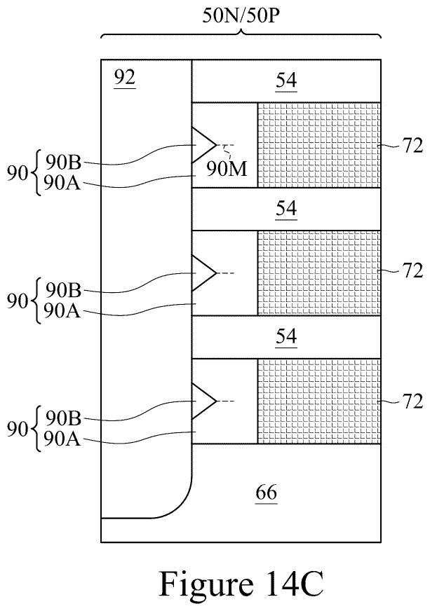

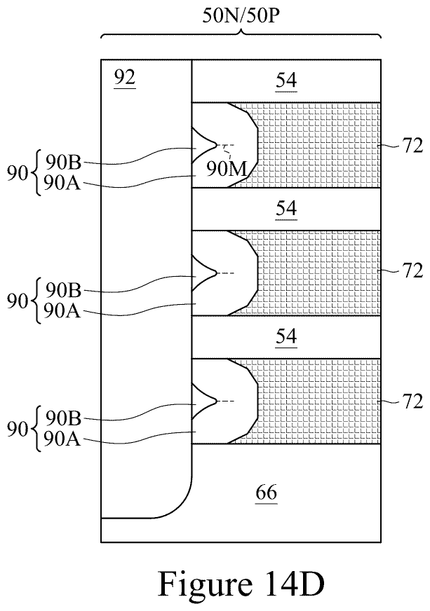

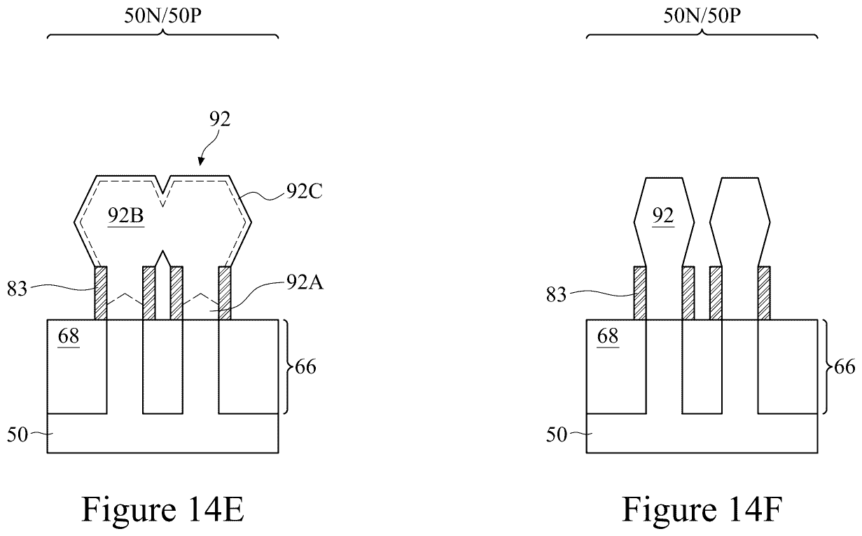

Forming the second inner spacer layer 90B as described above achieves various benefits. For example, the second inner spacer layer 90B has a high etch resistance during subsequent processes, such as during etching the first and second inner spacer layers 90A/90B to form the inner spacers 90 and during formation of the epitaxial source/drain regions (see FIGS. 14A-14F). Presence of nitrogen in the concentrations described above assists in providing this etch resistance. Regarding some of the above described embodiments, presence of carbon further assists in providing this etch resistance. In addition, the dielectric constant of the second inner spacer layer 90B is low enough to ensure that the inner spacer 90 (see FIGS. 13A-H) will have a low effective dielectric constant. In some embodiments pursuant to the above description, the second inner spacer layer 90B has a low nitrogen concentration and a high oxygen concentration (e.g., the oxygen concentration being greater than the nitrogen concentration) which contributes to the low-k value for the second inner spacer layer 90B.

FIGS. 12C and 12D illustrate exemplary detailed views of various elements of FIG. 12B, including the second nanostructures 54, the fins 66, the sacrificial material 72, the first inner spacer layer 90A, and the second inner spacer layer 90B. As illustrated, the second inner spacer layer 90B may be conformally deposited along the recessed sidewalls of the first inner spacer layer 90A (e.g., within the recesses 87′). The second inner spacer layer 90B may be deposited with a thickness T₃ ranging from 30 Å to 70 Å, however any suitable thickness T₃ may be utilized to fill the recesses 87′. As illustrated, the second inner spacer layer 90B may be deposited without seams due to presence of the recesses 87′. The material selection and process for forming the second inner spacer layer 90B may also contribute to the seamless deposition.

In particular, FIG. 12D (e.g., of the practical embodiments) illustrates that an outward sidewall of the second inner spacer layer 90B may include dishing in locations laterally adjacent to the recesses 87′. For example, the dishing may have a depth D3 ranging from 1 Å to 20 Å. As such, the dishing may not extend into the recesses 87′ because the recesses 87′ may be filled with the second inner spacer layer 90B. In some embodiments (not specifically illustrated), the dishing may extend partially into the recesses 87′ so long as portions of the recesses 87′ between the second nanostructures 54 are filled by the second inner spacer layer 90B.

In some embodiments (not specifically illustrated), the second inner spacer layer 90B may be formed as a plurality of conformal layers. For example, each of the plurality of layers may comprise any of the materials and deposited by any of the processes described above in connection with the second inner spacer layer 90B. In some embodiments, a silicon oxycarbonitride layer is deposited first and a silicon nitride is deposited there-over. In other embodiments, a silicon nitride layer is deposited first and a silicon oxycarbonitride layer is deposited there-over. Optionally, the plurality of layers may be blended such that the second inner spacer layer 90B has a substantially consistent composition.

In FIGS. 13A-13H, the second inner spacer layer 90B and the first inner spacer layer 90A are etched to form the inner spacers 90. The first and second inner spacer layers 90A/90B may be etched by an anisotropic etching process, such as RIE, NBE, or the like. The etching process removes the first and second inner spacer layers 90A/90B from the sidewalls of the second nanostructures 54 so that remaining portions of the first and second inner spacer layers 90A/90B are substantially level with the sidewalls of the second nanostructures 54. As discussed above, the etch resistance of the second inner spacer layer 90B prevents or reduces dishing that may occur during the etch process. In particular, the second inner spacer layer 90B (as well as the first inner spacer layer 90A) are etched by the directional etching and remain substantially unetched in the lateral direction (e.g., between the second nanostructures 54). In accordance with various embodiments, a single etching process may be used to simultaneously etch the first and second inner spacer layers 90A/90B. However, any suitable combination of etching processes may be used.

FIGS. 13C and 13D illustrate exemplary detailed views of various elements of FIG. 13B, including the second nanostructures 54, the fins 66, the sacrificial material 72, and the inner spacers 90. As illustrated, etching the first and second inner spacer layers 90A/90B results in discrete inner spacers 90 adjacent to the sacrificial material 72 and between the second nanostructures 54. In some embodiments, each remaining portion of the first inner spacer layer 90A may be partially bounded by and in physical contact with the sacrificial material 72, one or more of the second nanostructures 54, and/or one of the fins 66. In addition, each remaining portion of the second inner spacer layer 90B may be partially bounded by and in physical contact with the corresponding remaining portion of the first inner spacer layer 90A. As such, outward sidewalls of the inner spacers 90 are substantially level with the second nanostructures 54. As noted above, FIG. 13D (e.g., of the practical embodiments) provides depictions of the etch process that are analogous to those provided in the other figures among the FIG. 13 subset.

FIGS. 13E-13H illustrate embodiments having other shapes of various elements (e.g., the inner spacers 90). Although outward sidewalls of the inner spacers 90 are illustrated as being flush with sidewalls of the second nanostructures 54 (see, e.g., FIGS. 13B-13D), the outward sidewalls of the inner spacers 90 may extend beyond or be recessed from sidewalls of the second nanostructures 54 (see, e.g., FIGS. 13E and 13F). In cases of the outward sidewalls of the inner spacers 90 being recessed, the amount of dishing is reduced due to the compositions of the components of the inner spacers 90 (e.g., the second inner spacer layer 90B) causing those components to be resistant to lateral etching. Moreover, although the inward sidewalls of the inner spacers 90 are illustrated as being straight (see, e.g., FIGS. 13B and 13C), the inward sidewalls of the inner spacers 90 may be concave or convex (see, e.g., FIGS. 13D-13H). As an example, FIGS. 13E and 13F illustrate an embodiment in which sidewalls of the sacrificial material 72 are concave, inward sidewalls of the inner spacers 90 are concave, and the outward sidewalls of the inner spacers 90 are concave and recessed from the sidewalls of the second nanostructures 54. Other configurations are also possible. For example, FIGS. 13G and 13H illustrate an embodiment in which sidewalls of the sacrificial material 72 are concave, the inward sidewalls of the inner spacers 90 are concave, and the outward sidewalls the inner spacers 90 are straight and flush with the sidewalls of the second nanostructures 54.

In FIGS. 14A-14F, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

FIGS. 14C and 14D illustrate exemplary detailed views of various elements of FIG. 14B, including the second nanostructures 54, the fins 66, the sacrificial material 72, the inner spacers 90, and the epitaxial source/drain regions 92. As illustrated, after initially forming over and along the fins 66 and the sidewalls of the second nanostructures 54, portions of the epitaxial source/drain regions 92 converge and form over and along the outward sidewalls of the inner spacers 90. In addition, the second inner spacer layer 90A may be bounded entirely by the epitaxial source/drain regions 92 and the first inner spacer layer 90A. As noted above, FIG. 14D (e.g., of the practical embodiments) provides depictions of the epitaxial growth process that are analogous to those provided in the other figures among the FIG. 14 subset.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 14E. In other embodiments, adjacent epitaxial source/drain regions 92 remain separated after the epitaxy process is completed as illustrated by FIG. 14F. In the embodiments illustrated in FIGS. 14C and 14D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

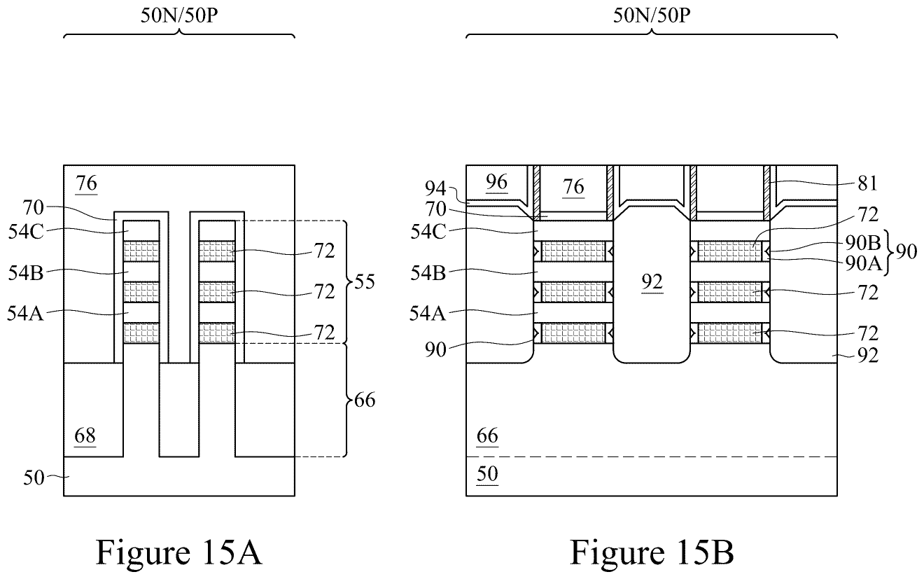

In FIGS. 15A and 15B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

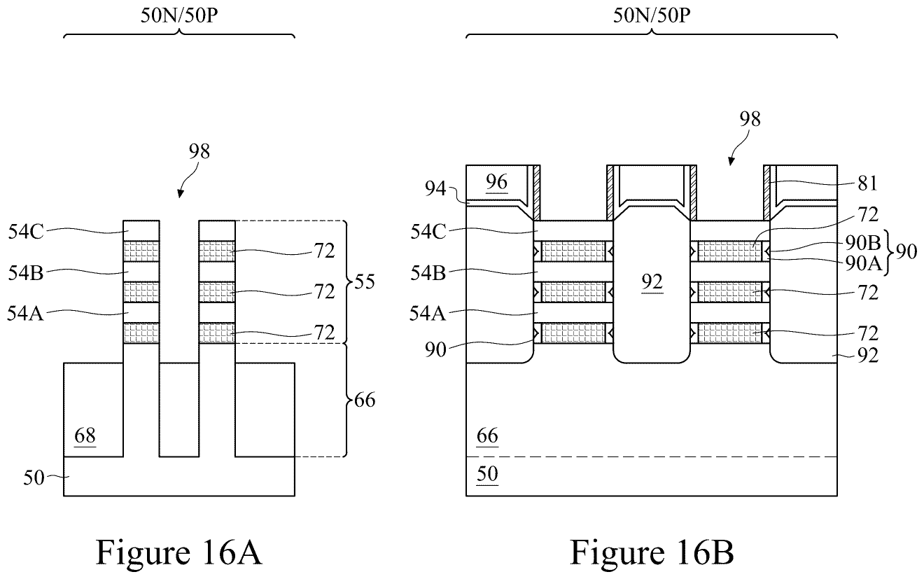

In FIGS. 16A and 16B, the dummy gates 76, and the masks 78 if present, are removed in one or more etching steps, so that second recesses 98 are formed. Portions of the dummy gate dielectrics 70 and portions of the protective liner 60 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

In FIGS. 17A-17D, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. As illustrated, extending the second recesses 98 may expose inward facing sidewalls of the inner spacers 90 (e.g., the first inner spacer layer 90A). The sacrificial material 72 may be completely removed, or a residue of the sacrificial material 72′ may remain on sidewalls of the inner spacers in the second recesses 98 (see, e.g., FIG. 17D).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

FIGS. 17C and 17D illustrate exemplary detailed views of various elements of FIG. 17B, including the second nanostructures 54, the fins 66, the inner spacers 90, the epitaxial source/drain regions 92, and the extended second recesses 98 after removal of the sacrificial material 72. As illustrated, the etch process may expose the inward sidewalls of the inner spacers 90 (e.g., the first inner spacer layer 90A). The exposed inner spacers 90 remain substantially unetched due to a high etch selectivity between the material of the sacrificial material 72 (e.g., silicon oxide) and the material of the first inner spacer layer 90A (e.g., silicon oxycarbide). As such, the first inner spacer layer 90A protects the second inner spacer layer 90B (as well as the inner spacer 90 in general) from being etched during removal of the sacrificial material 72.

In particular, FIG. 17D (e.g., of the practical embodiments) illustrates that the residue of the sacrificial material 72′ may remain on sidewalls of the inner spacers 90, such as in corners of the inner spacers 90 and the second nanostructures 54 (or the fins 66). This feature is notable in embodiments in which etching the sacrificial material 72 (see FIGS. 9A-9D) results in concave sidewalls (see, e.g., FIG. 9D), which creates narrower corners between the inner spacers 90 and the second nanostructures 54. The etchants may not reach these narrower corners to fully remove the sacrificial material 72. It should be appreciated that, in some embodiments (not specifically illustrated), the sidewalls of the sacrificial material and the inward sidewalls of the inner spacers 90 are substantially straight (see, e.g., FIGS. 17B and 17C) and yet the etch process to remove the sacrificial material 72 may still result in the residue of the sacrificial material 72′.

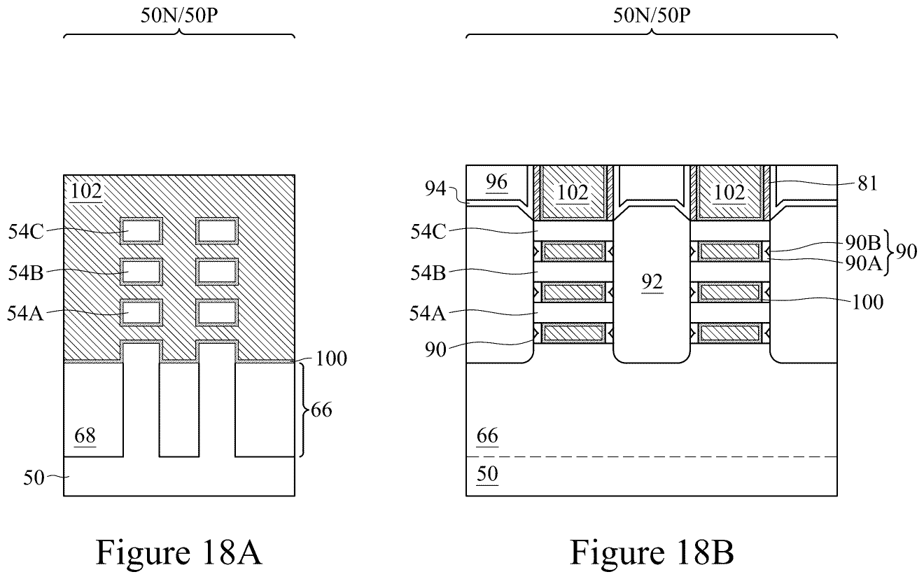

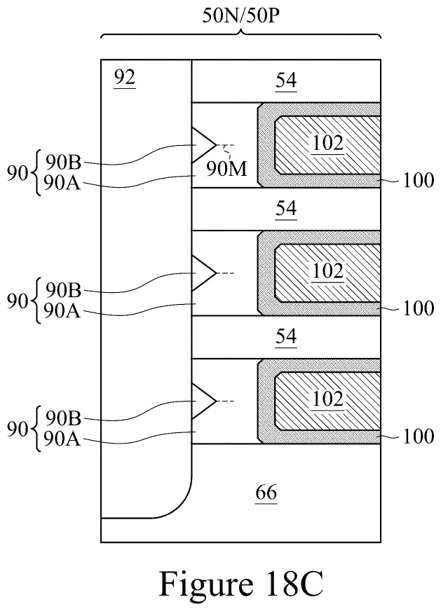

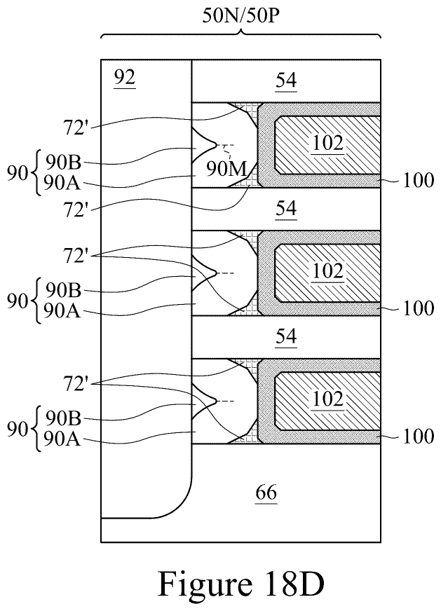

In FIGS. 18A-18D, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50, on top surfaces, sidewalls, and bottom surfaces of the second nanostructures 54, and on the inward sidewalls of the inner spacers 90 (if exposed). The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 18A-18D, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIGS. 18C and 18D illustrate exemplary detailed views of various elements of FIG. 18B, including the epitaxial source/drain regions 92, the gate dielectric layers 100, the gate electrodes 102, the second nanostructures 54, and the inner spacers 90. For example, the first inner spacer layer 90A of the inner spacer 90 may still include a portion of the seam 90M. In addition, as illustrated by FIG. 18D, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

FIGS. 18C and 18D illustrate exemplary detailed views of various elements of FIG. 18B, including the second nanostructures 54, the fins 66, the inner spacers 90, the epitaxial source/drain regions 92, residue of the sacrificial material 72′ (if present), the gate dielectric layers 100, and the gate electrode 102. As illustrated, the gate dielectric layers 100 may deposit along the inward sidewalls of the inner spacers 90 (e.g., the first inner spacer layer 90A) as well as upper and lower surfaces of the second nanostructures 54 (and upper surfaces of the fins 66). As a result, the inner spacers 90 may be bounded by the epitaxial source/drain region 92, the second nanostructures 54, and the gate dielectric layers 100. In addition, the first inner spacer layer 90A may therefore be bounded by those features along with the second inner spacer layer 90B. Further, the second inner spacer layer 90B may be bounded by the epitaxial source/drain region 92 and the first inner spacer layer 90A.

In particular, FIG. 18D (e.g., of the practical embodiments) illustrates that the residue of the sacrificial material 72′ may combine with the inner spacers 90 to form convex inward sidewalls upon which the gate dielectric layers 100 and the gate electrodes 102 are deposited. As illustrated, the inner spacers 90 may be bounded by the epitaxial source/drain region 92, the second nanostructures 54, and the gate dielectric layers 100 along with any residue of the sacrificial material 72′.

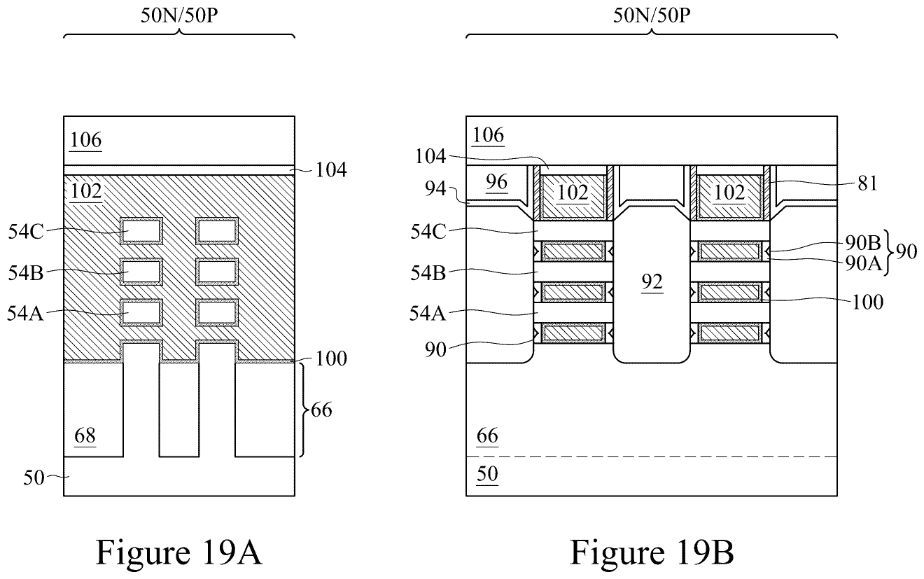

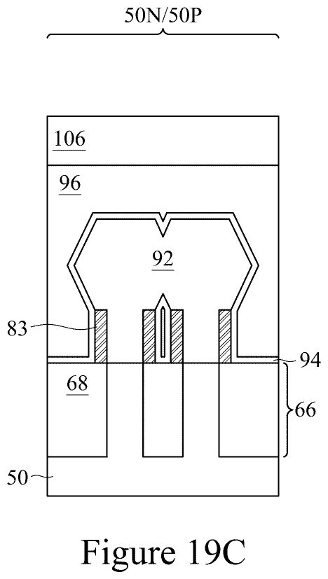

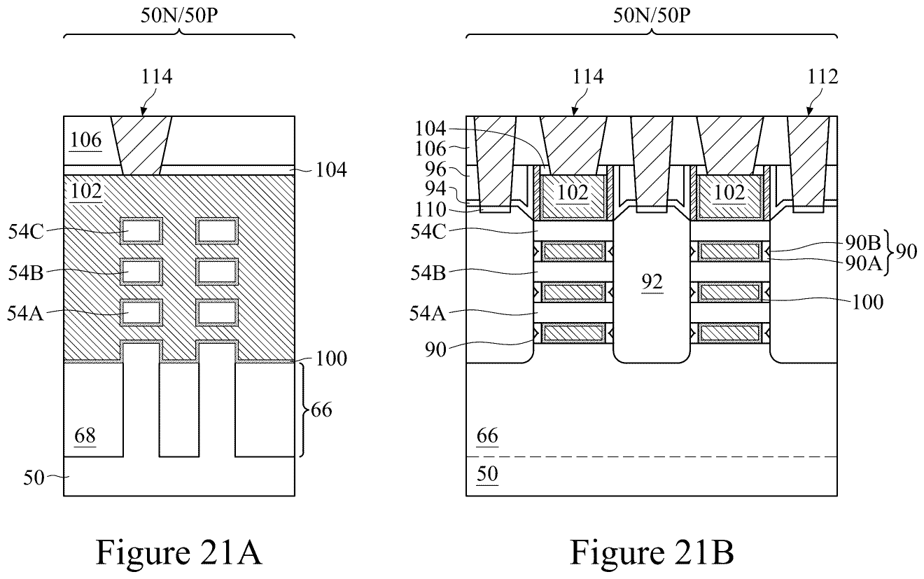

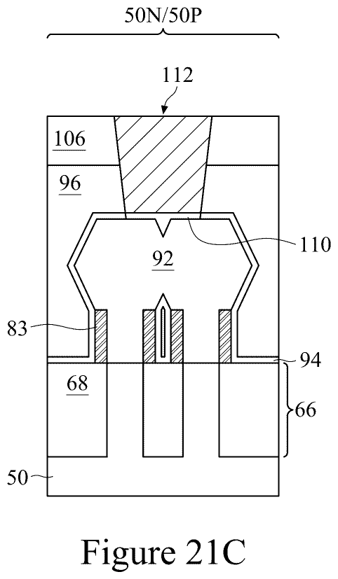

In FIGS. 19A-19C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 21A-21C) penetrate through the gate mask 104 to contact the top surface of the recessed gate electrodes 102.

As further illustrated, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

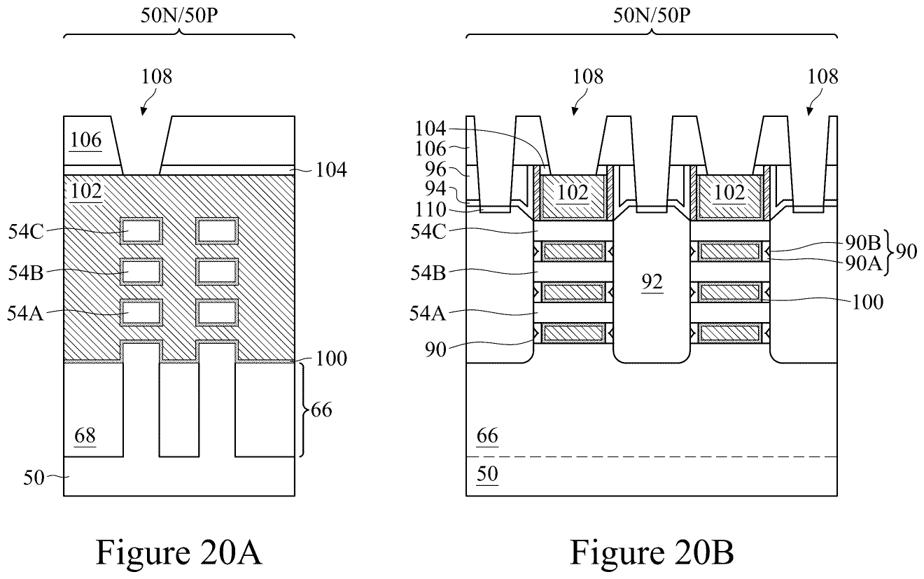

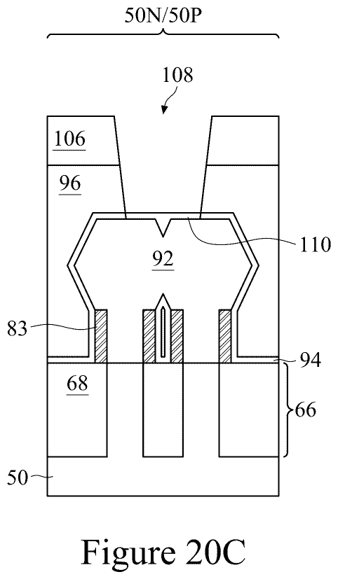

In FIGS. 20A-20C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 26B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 21A-21C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

Embodiments achieve various advantages. In particular, the disclosed embodiments form the inner spacers 90 with no seams or smaller seams by performing an etch process after depositing the first inner spacer layer 90A and before depositing the second inner spacer layer 90B. The etch process removes some or all of the seams 90M in the first inner spacer layer 90A and also provides a shallower (e.g., proportionately wider) window for deposition of the second inner spacer layer 90B free of seams or voids. The prevention or reduction of the seams lowers the effective dielectric constant (e.g., for C_{eff} reduction). In addition, compositions of the first and second inner spacer layers 90A/90B provide benefits to controlling the effective dielectric constant (e.g., ensuring a low-k) and shape of the inner spacers 90. In regard to the latter benefit, the first and second inner spacer layers 90A/90B have high etch resistances and have high etch selectivities in comparison with features like the sacrificial material 72 to prevent undesired etching of the inner spacers 90. This results is little to no dishing along the outward sidewalls of the inner spacers 90. Nano-FETs fabricated pursuant to these embodiments may be manufactured at a greater yield and function with improved reliability and performance.

In an embodiment, a method includes forming a first nanostructure and a second nanostructure over a substrate, the first nanostructure being interposed between the substrate and the second nanostructure; etching a first sidewall of the first nanostructure to be recessed from a second sidewall of the second nanostructure; depositing a first dielectric layer along the first sidewall, the second sidewall, and the substrate; etching a recess in the first dielectric layer, the recess extending toward the first sidewall of the first nanostructure; depositing a second dielectric layer in the recess over the first dielectric layer; and removing the first dielectric layer and the second dielectric layer from the second sidewall and the substrate. In another embodiment, the method further includes forming a source/drain region over the substrate and the second sidewall of the second nanostructure, wherein the source/drain region is in physical contact with the first dielectric layer and the second dielectric layer. In another embodiment, the method further includes, after removing the first dielectric layer and the second dielectric layer from the second sidewall, etching the first nanostructure to form an opening between the substrate and the second nanostructure. In another embodiment, etching the first nanostructure comprises exposing the first dielectric layer at the opening. In another embodiment, after etching the first nanostructure: a first portion of the first nanostructure is in physical contact with the substrate and the first dielectric layer; and a second portion of the first nanostructure is in physical contact with the second nanostructure and the first dielectric layer. In another embodiment, the first nanostructure comprises a first crystalline semiconductor material, wherein the second nanostructure comprises a second crystalline semiconductor material, and wherein the first crystalline semiconductor material is different from the second crystalline semiconductor material. In another embodiment, the first nanostructure comprises an oxide, and wherein the second nanostructure comprises a crystalline semiconductor material. In another embodiment, forming the first nanostructure and the second nanostructure over the substrate comprises: forming a silicon germanium layer over the substrate; forming the second nanostructure over the silicon germanium layer; forming a dummy gate structure over the second nanostructure; and replacing the silicon germanium layer with the first nanostructure.

In an embodiment, a semiconductor device includes a first nanostructure and a second nanostructure disposed over a substrate; a source/drain region being interposed between with a first sidewall of the first nanostructure and a second sidewall of the second nanostructure; a gate dielectric layer being interposed between an upper surface of the first nanostructure and a lower surface of the second nanostructure, the upper surface facing the lower surface; in a cross-section, a gate electrode disposed between the first nanostructure and the second nanostructure; and in the cross-section, an inner spacer disposed between the first nanostructure, the second nanostructure, the source/drain region, and the gate dielectric layer, the inner spacer comprising: a first inner spacer layer being disposed between the first nanostructure, the second nanostructure, the source/drain region, and the gate dielectric layer; and a second inner spacer layer being disposed between the source/drain region and the first inner spacer layer. In another embodiment, the first inner spacer layer comprises a silicon oxycarbide. In another embodiment, the second inner spacer layer comprises an oxycarbonitride. In another embodiment, the semiconductor device further includes a first oxide material being in physical contact with the first nanostructure, the first inner spacer layer, and the gate dielectric layer; and a second oxide material being in physical contact with the second nanostructure, the first inner spacer layer, and the gate dielectric layer. In another embodiment, in the cross-section, the second inner spacer layer is bounded entirely by the source/drain region and the first inner spacer layer. In another embodiment, the first inner spacer layer comprises a seam extending from the first inner spacer layer toward the gate dielectric layer and the gate electrode.

In an embodiment, a semiconductor device includes a first nanostructure disposed over a substrate; a second nanostructure disposed over the first nanostructure; a gate electrode and a gate dielectric layer disposed between the first nanostructure and the second nanostructure; a first inner spacer layer disposed between the first nanostructure and the second nanostructure, the first inner spacer layer being disposed between the gate dielectric layer, a first sidewall of the first inner spacer layer being level with a sidewall of the first nanostructure, a second sidewall of the first inner spacer layer being level with a sidewall of the second nanostructure; a second inner spacer layer disposed between the first nanostructure and the second nanostructure, a third sidewall of the second inner spacer layer being level with the first sidewall and the second sidewall; and a source/drain region disposed over the substrate, the source/drain region being adjacent with the first nanostructure, the second nanostructure, the first inner spacer layer, and the second inner spacer layer. In another embodiment, the first inner spacer layer comprises silicon oxycarbide. In another embodiment, the second inner spacer layer comprises an oxycarbonitride. In another embodiment, the second inner spacer layer comprises boron oxycarbonitride. In another embodiment, the first inner spacer layer comprises a seam, wherein a first end of the seam is located at an interface between the first inner spacer layer and the second inner spacer layer, and wherein a second end of the seam is located within a bulk portion of the first inner spacer layer. In another embodiment, in a cross-section the first inner spacer layer has a sideways U-shape, wherein in the cross-section the second inner spacer layer is disposed within the sideways U-shape, and wherein in the cross-section the second inner spacer layer has a triangular shape.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first nanostructure and a second nanostructure over a substrate, the first nanostructure being interposed between the substrate and the second nanostructure;
etching a first sidewall of the first nanostructure to be recessed from a second sidewall of the second nanostructure;
depositing a first dielectric layer along the first sidewall, the second sidewall, and the substrate;
etching a recess in the first dielectric layer, the recess extending toward the first sidewall of the first nanostructure;
depositing a second dielectric layer in the recess over the first dielectric layer; and
removing the first dielectric layer and the second dielectric layer from the second sidewall and the substrate.

2. The method of claim 1, further comprising forming a source/drain region over the substrate and the second sidewall of the second nanostructure, wherein the source/drain region is in physical contact with the first dielectric layer and the second dielectric layer.

3. The method of claim 2, further comprising, after removing the first dielectric layer and the second dielectric layer from the second sidewall, etching the first nanostructure to form an opening between the substrate and the second nanostructure.

4. The method of claim 3, wherein etching the first nanostructure comprises exposing the first dielectric layer at the opening.

5. The method of claim 4, wherein after etching the first nanostructure:
a first portion of the first nanostructure is in physical contact with the substrate and the first dielectric layer; and
a second portion of the first nanostructure is in physical contact with the second nanostructure and the first dielectric layer.

6. The method of claim 1, wherein the first nanostructure comprises a first crystalline semiconductor material, wherein the second nanostructure comprises a second crystalline semiconductor material, and wherein the first crystalline semiconductor material is different from the second crystalline semiconductor material.

7. The method of claim 1, wherein the first nanostructure comprises an oxide, and wherein the second nanostructure comprises a crystalline semiconductor material.

8. The method of claim 7, wherein forming the first nanostructure and the second nanostructure over the substrate comprises:
forming a silicon germanium layer over the substrate;
forming the second nanostructure over the silicon germanium layer;
forming a dummy gate structure over the second nanostructure; and
replacing the silicon germanium layer with the first nanostructure.

9. A semiconductor device, comprising:
a first nanostructure and a second nanostructure disposed over a substrate;
a source/drain region being interposed between with a first sidewall of the first nanostructure and a second sidewall of the second nanostructure;
a gate dielectric layer being interposed between an upper surface of the first nanostructure and a lower surface of the second nanostructure, the upper surface facing the lower surface;
in a cross-section, a gate electrode disposed between the first nanostructure and the second nanostructure; and
in the cross-section, an inner spacer disposed between the first nanostructure, the second nanostructure, the source/drain region, and the gate dielectric layer, the inner spacer comprising:
a first inner spacer layer being disposed between the first nanostructure, the second nanostructure, the source/drain region, and the gate dielectric layer; and
a second inner spacer layer being disposed between the source/drain region and the first inner spacer layer.

10. The semiconductor device of claim 9, wherein the first inner spacer layer comprises a silicon oxycarbide.

11. The semiconductor device of claim 10, wherein the second inner spacer layer comprises an oxycarbonitride.

12. The semiconductor device of claim 9, further comprising:
a first oxide material being in physical contact with the first nanostructure, the first inner spacer layer, and the gate dielectric layer; and
a second oxide material being in physical contact with the second nanostructure, the first inner spacer layer, and the gate dielectric layer.

13. The semiconductor device of claim 9, wherein in the cross-section, the second inner spacer layer is bounded entirely by the source/drain region and the first inner spacer layer.

14. The semiconductor device of claim 9, wherein the first inner spacer layer comprises a seam extending from the first inner spacer layer toward the gate dielectric layer and the gate electrode.

15. A semiconductor device, comprising:
a first nanostructure disposed over a substrate;
a second nanostructure disposed over the first nanostructure;
a gate electrode and a gate dielectric layer disposed between the first nanostructure and the second nanostructure;
a first inner spacer layer disposed between the first nanostructure and the second nanostructure, the first inner spacer layer being disposed between the gate dielectric layer, a first sidewall of the first inner spacer layer being level with a sidewall of the first nanostructure, a second sidewall of the first inner spacer layer being level with a sidewall of the second nanostructure;
a second inner spacer layer disposed between the first nanostructure and the second nanostructure, a third sidewall of the second inner spacer layer being level with the first sidewall and the second sidewall; and
a source/drain region disposed over the substrate, the source/drain region being adjacent with the first nanostructure, the second nanostructure, the first inner spacer layer, and the second inner spacer layer.

16. The semiconductor device of claim 15, wherein the first inner spacer layer comprises silicon oxycarbide.

17. The semiconductor device of claim 15, wherein the second inner spacer layer comprises an oxycarbonitride.

18. The semiconductor device of claim 17, wherein the second inner spacer layer comprises boron oxycarbonitride.

19. The semiconductor device of claim 15, wherein the first inner spacer layer comprises a seam, wherein a first end of the seam is located at an interface between the first inner spacer layer and the second inner spacer layer, and wherein a second end of the seam is located within a bulk portion of the first inner spacer layer.

20. The semiconductor device of claim 15, wherein in a cross-section the first inner spacer layer has a sideways U-shape, wherein in the cross-section the second inner spacer layer is disposed within the sideways U-shape, and wherein in the cross-section the second inner spacer layer has a triangular shape.
